(19) United States
(12) Patent Application Publication
(10) Pub. No.: US 2021/0336092 A1
(43) Pub. Date: Oct. 28, 2021

(54) LED WITH STACKED STRUCTURE

(71) Applicant: ALLIX CO., LTD., Jeollabuk-do (KR)

(72) Inventors: Jong-Uk An, Jeollabuk-do (KR); Jeong Hwan Park, Jeollabuk-do (KR); Jai Gon Shim, Gwangju (KR); Jeong Bin Bae, Jeollabuk-do (KR); Hyun Woo Cheong, Jeollabuk-do (KR)

(21) Appl. No.: 16/620,968

(22) PCT Filed: Nov. 26, 2019
(86) PCT No.: PCT/KR2019/016303

§ 371 Date: Dec. 10, 2019

(30) Foreign Application Priority Data
Nov. 6, 2019 (KR) 10-2019-0140951

(51) Int. Cl. H01L 33/48; H01L 33/20; H01L 33/52; H01L 33/50; H05K 3/00

(52) U.S. Cl. CPC H01L 33/483; H01L 33/20; H01L 33/52; H01L 2933/0033; H01L 33/502; H05K 3/0094; H05K 2201/10106; H01L 33/505

(57) ABSTRACT

The present disclosure relates to an LED board with a stacked structure, which includes: a metal plate; a printed circuit board attached onto an upper side of the metal plate and having at least one through-hole exposing a part of the upper side of the metal plate; at least one LED chip mounted on the metal plate exposed through the through-hole; a stacked portion having a phosphor-accommodating hole larger than the through-hole formed to include the LED chip and coupled onto the printed circuit board; and a phosphor filled in the phosphor-accommodating hole to cover the LED chip.

### TECHNICAL FIELD

The present disclosure relates to an LED board with a stacked structure, more particularly to an LED board with a stacked structure, wherein the structural stability of a circuit board is ensured because a metal plate, a printed circuit board and a stacked portion are arranged in a laminated manner, the convenience of manufacture is provided so that a phosphor can be cured stably, a variety of circuit patterns can be formed because the printed circuit board is arranged between the metal plate and the stacked portion, and light interference by adjacent light sources can be prevented because the light emitted from various light sources is controlled individually.

### BACKGROUND ART

The existing light-emitting diode module is generally manufactured by completing light-emitting diode chips as individual packages and then mounting the light-emitting diode packages on a printed circuit board with specific arrangement and circuitry suited the purpose of use. But, a COB (chip on board)-type light-emitting diode module has been developed recently. The COB-type light-emitting diode module is a light-emitting diode module wherein light-emitting diode chips are directly packaged on a printed circuit board according to the purpose of use so as to omit the procedure of forming individual packages.

In order to emit light from an LED, a diode and a conducting wire communicated with the diode are necessary. In addition, a reflective material for preventing waste of the emitted light, a light-transmitting material which attenuates light less, a light-focusing member (e.g., a lens) for orienting light to a predetermined direction, a fluorescent material for controlling the color of the emitted light, etc. are used. In addition, measures for conducting and dissipating heat generated during conversion of electricity to light are also required.

An LED module board is equipped with a package board, e.g., a device board, a blue LED chip mounted on the device board, which is, preferably, a plurality of semiconductor light-emitting devices, and a circuit pattern. It is also equipped with a resin layer including a phosphor, a reflective layer, an adhesive layer and a light-diffusing lens.

However, the existing package is mainly prepared by forming a circuit pattern of a metal thin-film layer on a thermoplastic resin (mainly polyphthalamide) and the circuit pattern wherein copper is used is generally plated with silver (Ag) in consideration of light reflectivity. The silver plating causes the problem of interpolar insulation of the circuit due to oxidation.

In addition, heat generation from a high-power LED is an imminent problem. Because 90% of the energy applied to the LED is consumed as heat and soldering is employed for the mounting of the LED, the mounted LED device may be detached if the temperature rises above the melting temperature of lead. In addition, optical efficiency and the lifespan of the light source may also be negatively affected.

### DISCLOSURE OF THE INVENTION

### Technical Problem

The present disclosure is directed to providing an LED board with a stacked structure, wherein the structural stability of a circuit board is ensured because a metal plate, a printed circuit board and a stacked portion are arranged in a laminated manner, the convenience of manufacture is provided so that a phosphor can be cured stably, a variety of circuit patterns can be formed because the printed circuit board is arranged between the metal plate and the stacked portion, and light interference by adjacent light sources can be prevented because the light emitted from various light sources is controlled individually.

The purpose of the present disclosure is not limited to that described above and other purposes will be clearly understood by those of ordinary skill in the art to which the present disclosure belongs from the following description.

### Technical Solution

An LED board with a stacked structure according to an exemplary embodiment of the present disclosure includes: a metal plate; a printed circuit board attached onto an upper side of the metal plate and having at least one through-hole exposing a part of the upper side of the metal plate; at least one LED chip mounted on the metal plate exposed through the through-hole; a stacked portion having a phosphor-accommodating hole formed to include the LED chip and coupled onto the printed circuit board; and a phosphor filled in the phosphor-accommodating hole to cover the LED chip.

The stacked portion may be formed of aluminum or copper.

The stacked portion may be equipped with at least one partition dividing the inner circumference of the phosphor-accommodating hole, and may be formed with a predetermined height so as to accommodate the phosphor in the formed space.

The phosphor-accommodating hole may be formed with one of a circular shape or a polygonal shape.

The LED chip may be arranged in a COB (chip on the board) manner.

### Advantageous Effects

An LED board with a stacked structure according to the present disclosure may be coupled onto a circuit board so as to ensure the structural stability of the circuit board.

In addition, the durability of a LED chip may be improved by effectively dissipating heat generated from the LED chip, thereby reducing load applied to the LED chip.

Furthermore, a phosphor-accommodating hole formed in a stacked portion can provide the convenience of manufacturing by allowing a phosphor to be cured stably.

Besides, light interference by adjacent light sources can be prevented by controlling the light emitted from various light sources individually.

Additionally, a plurality of light sources can be formed into various patterns because various circuit patterns can be formed by arranging a printed circuit board between a metal plate and a stacked portion.

The advantageous effects of the present disclosure are not limited to those described above. Other effects not mentioned above will be clearly understood by those of ordinary skill in the art to which the present disclosure belongs from the following description.

### BRIEF DESCRIPTION OF THE DRAWINGS

FIG. 1 is a perspective view of an LED board with a stacked structure according to a first exemplary embodiment of the present disclosure.

FIG. 2 is a perspective view of an LED board with a stacked structure according to a second exemplary embodiment of the present disclosure.

FIG. 3 is a perspective view of an LED board with a stacked structure according to a third exemplary embodiment of the present disclosure.

FIG. 4 is a perspective view of an LED board with a stacked structure according to a fourth exemplary embodiment of the present disclosure.

FIG. 5 is a perspective view of an LED board with a stacked structure according to a fifth exemplary embodiment of the present disclosure.

### MODE FOR CARRYING OUT THE INVENTION

Hereinafter, the specific exemplary embodiments of the present disclosure are described in detail referring to the attached drawings. In the attached drawings, the same reference numerals refer to the same elements. Descriptions of known functions and constitutions may be omitted to avoid obscuring the subject matter of the present disclosure. For the same reason, some elements are exaggerated, omitted or simplified in the attached drawings.

Throughout the specification, unless explicitly described to the contrary, the expression “include” implies the inclusion of the stated elements but not the exclusion of any other elements. Further, throughout the specification, the expression “on” means being positioned on or below the particular portion, and does not necessarily mean being positioned on the upper side of the portion based on a gravitational direction.

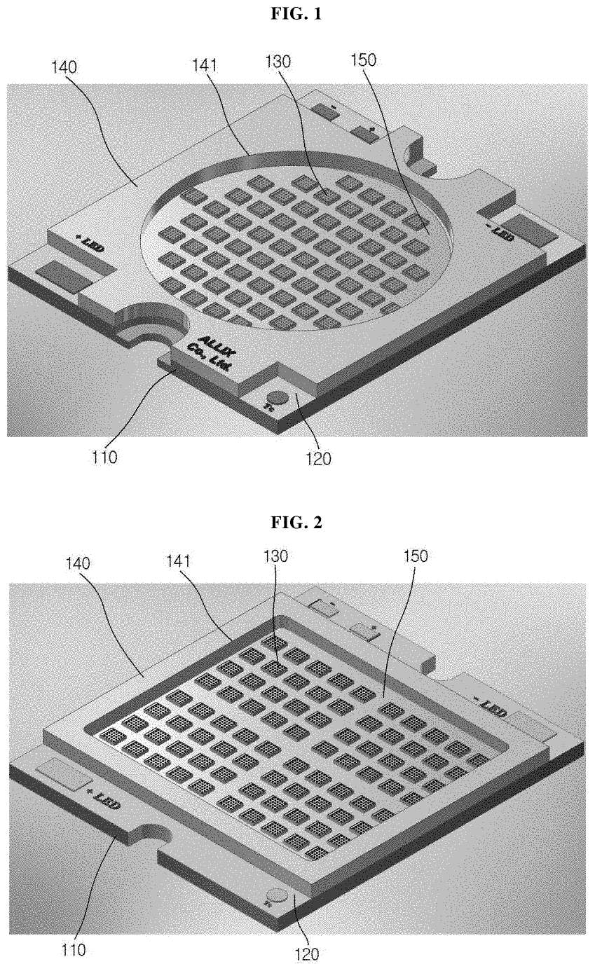

FIG. 1 is a perspective view of an LED board with a stacked structure according to a first exemplary embodiment of the present disclosure, and FIG. 2 is a perspective view of an LED board with a stacked structure according to a second exemplary embodiment of the present disclosure.

Referring to FIG. 1 and FIG. 2, an LED board with a stacked structure according to first and second exemplary embodiments of the present disclosure includes a metal plate 110, a printed circuit board 120, an LED chip 130, a stacked portion 140 and a phosphor 150.

The metal plate 110 may be formed of aluminum, copper, etc. having superior thermal conductivity and light reflectivity. In addition, an adhesive layer (not shown) may be formed on the surface of the metal plate 110 so that the printed circuit board 120 can be adhered.

The printed circuit board 120 may be bonded by an adhesive layer as described above. At least one through-hole exposing a part of the upper side of the metal plate 110 may be formed. A space in which the LED chip 130 can be mounted is formed in the through-hole as the metal plate 110 is exposed. In particular, the printed circuit board 120 is arranged between the metal plate 110 and the stacked portion 140 so as to form various circuit patterns.

The LED chip 130 is mounted on the metal plate 110 exposed through the through-hole. The LED chip 130 may arranged on the metal plate 110 in a COB (chip on the board) manner.

The stacked portion 140 has a phosphor-accommodating hole 141, which is larger than the through-hole (not shown) formed on the printed circuit board 120, formed to include the at least one LED chip 130, and is bonded on the printed circuit board 120. Although the stacked portion 140 is formed as a rectangular shape in the present disclosure, the shape is not limited thereto. Specifically, the stacked portion 140 may be formed to have a size of 5-200 mm. However, the size of the stacked portion 140 is not limited thereto but may be determined variously depending on the arrangement of the LED chip 130.

And, although the shape of the phosphor-accommodating hole 141 formed in the stacked portion 140 is illustrated as a circular shape or a rectangular shape in FIGS. 1 and 2, the shape is not limited thereto. It may also be a polygonal shape and the shape is not limited as long as the phosphor 150 can be accommodated through the phosphor-accommodating hole 141. In addition, the stacked portion 140 may have a plurality of cut portions 143 formed to be connected to the printed circuit board 120 and an electrode.

The stacked portion 140 may be formed of aluminum or copper. Specifically, it may be formed of aluminum. If the stacked portion 140 is may be formed of aluminum, the heat generated by the LED chip 130 can be dissipated effectively. As a result, the durability of the LED chip 130 can be improved.

The stacked portion 140 may form a dam extended upward by a predetermined height so as to accommodate the phosphor 150. If the stacked portion 140 is bonded to the upper side of the printed circuit board 120, a dam is formed along the inside of the phosphor-accommodating hole 141. Thus, it is not necessary to form a dam additionally through the phosphor-accommodating hole 141 of the stacked portion 140, and the phosphor can accommodate a plurality of the LED chips 130 mounted on the printed circuit board 120 at once, which makes manufacturing more convenient. In addition, because the stacked portion 140 forms a dam integrally with the phosphor-accommodating hole 141, the phosphor can be cured stably without overflowing sideways. This provides overall structural stability. In addition, because the phosphor is accommodated stably in the phosphor-accommodating hole 141, light interference can be prevented and, thus, light for special use may be provided.

The phosphor 150 is filled in the phosphor-accommodating hole 141 to cover the LED chip 130. The phosphor 150 may be accommodated more stably by a partition 142 dividing the inner circumference of the phosphor-accommodating hole 141.

On the other hand, the dam formed on the existing printed circuit board is inconvenient for manufacturing because it is made of a resin material and is formed to accommodate each LED chip. The resin may induce light interference. Therefore, when a plurality of LED chips is used, there may occur problems in providing light for special use due to light interference.

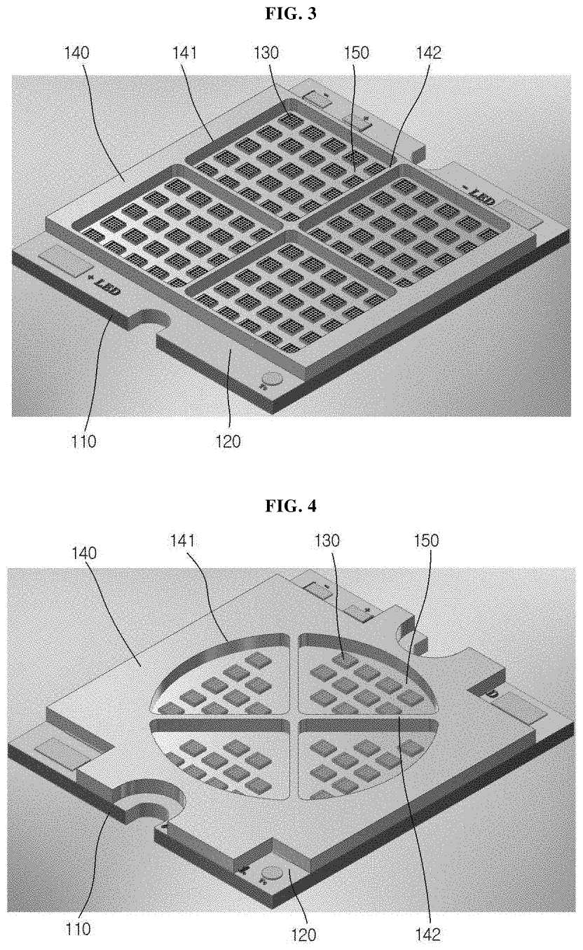

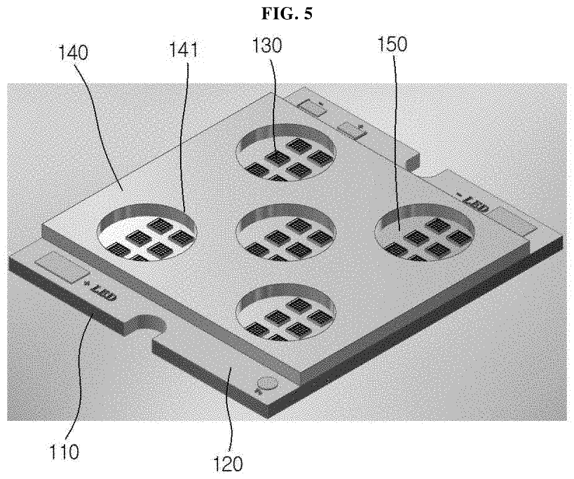

FIG. 3 is a perspective view of an LED board with a stacked structure according to a third exemplary embodiment of the present disclosure, FIG. 4 is a perspective view of an LED board with a stacked structure according to a fourth exemplary embodiment of the present disclosure, and FIG. 5 is a perspective view of an LED board with a stacked structure according to a fifth exemplary embodiment of the present disclosure.

First, referring to FIG. 3 and FIG. 4, a stacked portion 140 may be equipped with a partition 142 which divides the inner circumference of a phosphor-accommodating hole 141 into a plurality of spaces. If the phosphor-accommodating hole 141 is divided, a phosphor can be accommodated more stably therein. In addition, it is possible to mount LED chips of various colors in the respective spaces. Because the LED chips are completely separated physically by the partition 142, light interference can be minimized and the efficiency of the LED light source can be enhanced. The division by the partition 142 can be achieved variously based on the type and number of the mounted LED chips and circuit design, not being limited to the alternating patterns illustrated in FIG. 3 and FIG. 4.

Also, as shown in FIG. 5, a phosphor-accommodating hole 141 may be formed on a stacked portion 140 with a predetermined pattern, and then an LED chip may be mounted. The above-described effects can be achieved even when the stacked portion 140 is arranged with the shape shown in FIG. 5. It is obvious that the shape is not limited to the circular shape shown in FIG. 5 and may be formed as a polygonal shape.

As described, the LED board with a stacked structure according to the present disclosure may be coupled onto the circuit board so as to ensure the structural stability of the circuit board. In addition, the durability of the LED chip may be improved by effectively dissipating heat generated from the LED chip, thereby reducing load applied to the LED chip. Furthermore, the phosphor-accommodating hole formed in the stacked portion can provide the convenience of manufacturing by preventing the phosphor from flowing. Besides, light interference by adjacent light sources can be prevented by controlling the light emitted from various light sources individually. Additionally, a plurality of light sources can be formed into various patterns because various circuit patterns can be formed by arranging the printed circuit board between the metal plate and the stacked portion.

Those skilled in the art will appreciate that the conceptions and specific embodiments disclosed in the foregoing description may be readily utilized as a basis for modifying or designing other embodiments for carrying out the same purposes of the present disclosure. Those skilled in the art will also appreciate that such equivalent embodiments do not depart from the spirit and scope of the disclosure as set forth in the appended claims.

1. An LED board with a stacked structure, comprising:
a metal plate;
a printed circuit board attached onto an upper side of the metal plate and having at least one through-hole exposing a part of the upper side of the metal plate;
at least one LED chip mounted on the metal plate exposed through the through-hole;
a stacked portion having a phosphor-accommodating hole formed to include the LED chip and coupled onto the printed circuit board; and
a phosphor filled in the phosphor-accommodating hole to cover the LED chip.

2. The LED board with a stacked structure of claim 1, wherein the stacked portion is formed of aluminum or copper.

3. The LED board with a stacked structure of claim 1, wherein the stacked portion is equipped with at least one partition dividing the inner circumference of the phosphor-accommodating hole, and is formed with a predetermined height so as to accommodate the phosphor in the formed space.

4. The LED board with a stacked structure of claim 1, wherein the phosphor-accommodating hole is formed with one of a circular shape or a polygonal shape.

5. The LED board with a stacked structure of claim 1, wherein the LED chip is arranged in a COB (chip on the board) manner.

6. The LED board with a stacked structure of claim 1, wherein the phosphor-accommodating hole is larger than the through-hole formed on the printed circuit board.

7. An LED board with a stacked structure, comprising:
a metal plate;
a printed circuit board attached onto an upper side of the metal plate and having at least one through-hole exposing a part of the upper side of the metal plate;
at least one LED chip mounted on the metal plate exposed through the through-hole; and
a stacked portion having a phosphor-accommodating hole formed to include the LED chip and coupled onto the printed circuit board,
wherein the stacked portion includes a partition which divides an inner circumference of the phosphor-accommodating hole into a plurality of spaces.

8. The LED board with a stacked structure of claim 7, wherein the stacked portion is formed of aluminum or copper.

9. The LED board with a stacked structure of claim 7, wherein the phosphor-accommodating hole is formed with one of a circular shape or a polygonal shape.

10. The LED board with a stacked structure of claim 7, wherein the LED chip is arranged in a COB (chip on the board) manner.
